(19) United States
(12) Patent Application Publication
(10) Pub. No.: US 2024/0416660 A1
(43) Pub. Date: Dec. 19, 2024

(54) DISPLAY DEVICE AND METHOD FOR MANUFACTURING THE SAME

(71) Applicant: Samsung Display Co., LTD., Yongin-si (KR)

(72) Inventor: Eunseok KIM, Yongin-si (KR)

(21) Appl. No.: 18/588,341

(22) Filed: Feb. 27, 2024

(30) Foreign Application Priority Data
Jun. 13, 2023 (KR) 10-2023-0075547

(51) Int. Cl. B41J 2/175; B41J 2/18

(52) U.S. Cl. CPC B41J 2/17596; B41J 2/18

(57) ABSTRACT

A manufacturing apparatus for a display device includes: a stage on which a display substrate is mounted; an ink discharge module configured to discharge ink onto the display substrate; and an ink supply module configured to supply the ink to the ink discharge module, where the ink supply module is convertible between a first state in which the first ink circulation path is formed, and a second state in which the ink supply path is formed.

This application claims priority to Korean Patent Application No. 10-2023-0075547, filed on Jun. 13, 2023, and all the benefits accruing therefrom under 35 U.S.C. § 119, the content of which in its entirety is herein incorporated by reference.

### BACKGROUND

### 1. Field

One or more embodiments relate to an apparatus and method, and more particularly, to an apparatus for manufacturing a display device and a method of manufacturing a display device.

### 2. Description of the Related Art

An electronic device is widely used based on portability. A portable electronic device that has been widely used includes a small electronic device such as a mobile phone as well as a tablet personal computer (“PCs”).

In order to support various functions, the portable electronic device includes a display device for providing visual information such as an image to a user. As other components for driving the display device has been miniaturized, the proportion occupied by the display device in the electronic device is increasing, and structures that can be bent from a flat state to a certain angle are being developed.

### SUMMARY

One or more embodiments include an ink supply module that supplies ink with uniform quality and has a simplified structure.

However, these challenges are for example, and the challenges that the disclosure seeks to address are not limited to them.

Additional aspects will be set forth in part in the description which follows and, in part, will be apparent from the description, or may be learned by practice of the presented embodiments of the disclosure.

According to one or more embodiments, an apparatus for manufacturing a display device includes: a stage on which a display substrate is mounted; an ink discharge module configured to discharge ink onto the display substrate; and an ink supply module configured to supply the ink to the ink discharge module. The ink supply module includes: a first storage unit configured to store ink; a second storage unit configured to store the ink, and connected to the first storage unit and the ink discharge module; an ink tank configured to store the ink and to supply the ink to the first storage unit; a first flow path connecting the first storage unit and the second storage unit to each other so that a first ink circulation path is formed in which the ink circulates between the first storage unit and the second storage unit;, a second flow path connecting the second storage unit and the ink discharge module to each other so that a second ink circulation path is formed in which the ink circulates between the second storage unit and the ink discharge module; and a third flow path forming an ink supply path in which ink is supplied from the ink tank to the first storage unit, where the ink supply module is convertible between a first state in which the first ink circulation path is formed, and a second state in which the ink supply path is formed.

According to one or more embodiments, the ink supply module may further include a first valve configured to control the flow of the ink at a contact point of the first flow path and the third flow path.

According to one or more embodiments, the first valve may include: a 1-1 valve arranged on the first flow path, and a 1-2 valve arranged on the third flow path, where in the first state, the 1-1 valve is open and the 1-2nd valve is closed, and in the second state, the 1-1 valve is closed and the 1-2 valve is open.

According to one or more embodiments, the first flow path may include: a 1-1 flow path through which the ink stored in the first storage unit flows to the second storage unit, and a 1-2 flow path through which the ink stored in the second storage unit flows to the first storage unit, and the ink supply module may further include: a second valve arranged on the 1-1 flow path.

According to one or more embodiments, in the first state, the second valve may be open, and in the second state, the second valve may be closed.

According to one or more embodiments, the ink supply module may further include a pressure regulator configured to adjust pressure inside the second storage unit.

According to one or more embodiments, the pressure regulator may adjust the pressure inside the second storage unit such that the pressure inside the second storage unit is lower than the pressure inside the first storage unit.

According to one or more embodiments, the pressure inside the first storage unit may be atmospheric pressure.

According to one or more embodiments, the ink supply module may convert from the first state to the second state when a level of the ink stored in the second storage unit falls below a specified value.

According to one or more embodiments, the ink discharge module may include: a distributor connected to the second flow path and configured to distribute the ink to a plurality of sprayers; and the plurality of sprayers connected to the distributor and configured to spray the ink.

According to one or more embodiments, a method of manufacturing a display device includes: placing a display substrate on a stage; discharging ink onto the display substrate by an ink discharge module; and supplying the ink to the ink discharge module. The supplying of the ink to the ink discharge module includes: a first circulation process in which the ink circulates between the first storage unit and the second storage unit through a first flow path; a second circulation process in which the ink circulates between the second storage unit and the ink discharge module through a second flow path; and a supply process in which the ink flows from the ink tank to the first storage unit through a third flow path.

According to one or more embodiments, the supplying of the ink to the ink discharge module may further include: a process in which a first valve controls the flow of the ink at a contact point of the first flow path and the third flow path.

According to one or more embodiments, the first valve may include a 1-1 valve arranged on the first flow path, and a 1-2 valve arranged on the third flow path, where in the first circulation process, the 1-1 valve is open and the 1-2nd valve is closed, and in the supply process, the 1-1 valve is closed and the 1-2 valve is open.

According to one or more embodiments, the first flow path may include: a 1-1 flow path through which the ink stored in the first storage unit flows to the second storage unit, and a 1-2 flow path through which the ink stored in the second storage unit flows to the first storage unit, and a second valve may be arranged on the 1-1 flow path.

According to one or more embodiments, in the first circulation process, the second valve may be open, and in the supply process, the second valve may be closed.

According to one or more embodiments, the supplying of the ink to the ink discharge module may further include a pressure adjusting process to adjust the pressure inside the second storage unit.

According to one or more embodiments, the process of the adjusting the pressure may include adjusting the pressure of the second storage unit such that the pressure inside the second storage unit is lower than the pressure inside the first storage unit.

According to one or more embodiments, the pressure inside the first storage unit may be atmospheric pressure.

According to one or more embodiments, the supply process may begin when the ink stored in the second storage unit falls below a specified level.

According to one or more embodiments, the ink discharge module may include: a distributor connected to the second flow path and configured to distribute the ink to a plurality of sprayers, and the plurality of sprayers connected to the distributor and configured to spray the ink.

Other aspects, features and advantages other than those described above will become apparent from the following drawings, claims and detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a manufacturing apparatus of a display device according to an embodiment;

FIG. 2 to FIG. 5 are schematic cross-sectional views of an ink supply module and an ink discharge module according to an embodiment;

FIG. 6 is a plan view schematically illustrating a display device according to an embodiment;

FIG. 7 is a cross-sectional view schematically depicting a display device according to an embodiment; and

FIG. 8 is an equivalent schematic view of one pixel of a display panel according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure is subject to various modifications and may have many embodiments, certain of which are illustrated in the drawings and further described in the detailed description. The effects and features of the disclosure, and methods of achieving them will become clear with reference to the embodiments described below in detail together with the drawings. However, the disclosure is not limited to the embodiments described herein and may be implemented in various forms.

Hereinafter, embodiments will be described in detail with reference to the accompanying drawings, and when describing with reference to the drawings, the same or corresponding components are given the same reference numerals, and duplicate descriptions thereof will be omitted.

In the following embodiments, the terms “first”, “second”, etc. are not intended to be limiting, however are used to distinguish one component from another.

In the following embodiments, the singular expression includes the plural unless the context clearly indicates otherwise.

In the following embodiments, the terms “including” or “that has”, etc. are intended to imply the presence of the recited features or components and do not preclude the possibility of the addition of one or more other features or components.

In the following embodiments, when a portion of a film, area, component, etc. is the to be over or on top of another portion or connected to another portion, this includes not only when it is directly on top of another portion or directly connected to another portion, but also when there are other films, areas, components, etc. arranged therebetween.

In the drawings, components may be exaggerated or reduced in size for ease of illustration. For example, the size and thickness of each configuration shown in the drawings are arbitrary for purposes of illustration and the disclosure is not necessarily limited to those shown.

In the following embodiments, the terms x-axis, y-axis, and z-axis are not limited to, however may be interpreted in a broad sense to include, three axes in a Cartesian coordinate system. For example, the x-axis, y-axis, and z-axis may be orthogonal to each other, however, may also refer to different directions that are not orthogonal to each other.

In some embodiments, a particular sequence of processes may be performed in a different order than that described. For example, two processes described in succession may be performed substantially simultaneously, or may be performed in the opposite order from the order described.

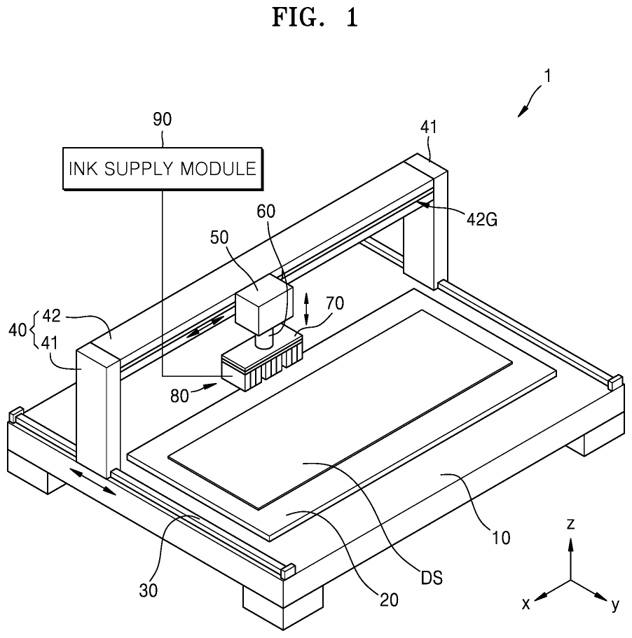

FIG. 1 is a schematic perspective view of a manufacturing apparatus for a display device, according to an embodiment.

Referring to FIG. 1, the manufacturing apparatus 1 for a display device may include a supporter 10, a stage 20, a guide portion 30, a first moving portion 40, a second moving portion 50, a third moving portion 60, a connection frame 70, an ink discharge module 80, and an ink supply module 90.

The supporter 10 may support the stage 20, the guide portion 30, the first moving portion 40, the second moving portion 50, the third moving portion 60, the connection frame 70, and the ink discharge module 80. Although the shape of the supporter 10 is shown as a hexahedron in FIG. 1, this is only an example, and the shape of the supporter 10 is not limited thereto.

The stage 20 may be disposed on the supporter 10. A display substrate DS may be mounted on the stage 20. The stage 20 may include align marks for aligning the display substrate DS. Here, the display substrate DS may be part of a display device being manufactured, and may be a target for the ink discharge module 80 to discharge ink onto. The stage 20 may form a work area for an inkjet printing process.

The guide portion 30 may be disposed on the supporter 10. In an embodiment, for example, two guide portions 30 may be provided, arranged spaced apart from each other at opposite sides with the stage 20 in between. The length of the guide portions 30 may be at least as long as the length of the edge of the display substrate DS. The guide portions 30 may guide the first moving portion 40 to perform linear motion along the longitudinal direction of the guide portion 30. In an embodiment, for example, the guide portion 30 may include a linear motion rail.

The first moving portion 40 is disposed on the supporter 10 and may be linearly reciprocated with respect to the stage 20. The first moving portion 40 may include a column member 41 and a horizontal member 42. In FIG. 1, the column member 41 and the horizontal member 42 are shown to have a cuboidal rod shape, but the shapes of the column member 41 and the horizontal member 42 are not limited thereto.

The column member 41 may be connected to the guide portion 30. In an embodiment, for example, two column members 41 may be provided, arranged at opposite sides with the stage 20 in between. The column members 41 may move along the longitudinal direction of the guide portion 30. The column members 41 may be manually linearly moved, or may be automatically linearly moved by means of a motor cylinder or the like. In an embodiment, for example, the column member 41 may be automatically linearly moved by including a linear motion block that moves along a linear motion rail.

The horizontal member 42 may be secured to the column member 41. The horizontal member 42 may be arranged between two column members 41. A horizontal groove 42G that has a longitudinal direction may be disposed on the horizontal member 42. The horizontal groove 42G may be disposed on one side of the horizontal member 42. The horizontal groove 42G may guide the second moving portion 50 to enable linear reciprocating movement along the longitudinal direction of the horizontal groove 42G.

The second moving portion 50 is connected to the first moving portion 40 and may be linearly reciprocated with respect to the first moving portion 40. In an embodiment, for example, at least a portion of the second moving portion 50 may be accommodated in the horizontal groove 42G of the horizontal member 42. The second moving portion 50 may move along the longitudinal direction of the horizontal groove 42G. In an embodiment, for example, the second moving portion 50 may include a linear motor or the like.

The third moving portion 60 is connected to the second moving portion 50 and may be linearly reciprocated with respect to the second moving portion 50. In an embodiment, for example, the third moving portion 60 may be disposed on a bottom side (for example, a side facing the -z-axis direction) of the second moving portion 50. Here, the bottom side (for example, the side facing the -z-axis direction) of the second moving portion 50 may be the side on which the second moving portion 50 faces the stage 20. In an embodiment, for example, the third moving portion 60 may include a pneumatic cylinder or the like. The third moving portion 60 may be rotated about a rotational axis, and for this purpose, the third moving portion 60 may include an electric motor, a pneumatic motor, etc.

The connection frame 70 may be connected to the third moving portion 60. In an embodiment, for example, the connection frame 70 may be disposed on a bottom side (for example, a side facing the -z-axis direction) of the third moving portion 60. Here, the bottom side (for example, the side facing the -z-axis direction) of the third moving portion 60 may be the side on which the third moving portion 60 faces the stage 20. The movement directions of the first moving portion 40, the second moving portion 50, and the third moving portion 60 may intersect each other. In such a structure, the connection frame 70 may freely move to a specified position in three dimensions.

The ink discharge module 80 may be connected to the connection frame 70. In an embodiment, for example, the ink discharge module 80 may be disposed on a bottom side (for example, a side facing the -z-axis direction) of the connection frame 70. Here, the bottom side (for example, the side facing the -z-axis direction) of the connection frame 70 may be the side on which the connection frame 70 faces the stage 20. In such a structure, the ink discharge module 80 may freely move to a specified position in three dimensions. The ink discharge module 80 may discharge ink onto the display substrate DS.

The ink may adhere to the display substrate DS and form some layers of the display device. In this case, the ink may be a polymeric or low-molecular-weight organic material corresponding to an emission layer of an organic light-emitting display device. In another embodiment, the ink may be a red, green, or blue colored liquid including pigment particles mixed in a liquid crystal, an alignment solution, or a solvent. In yet another embodiment, the ink may include a solution containing inorganic materials such as quantum dot materials or the like.

The ink supply module 90 may supply ink to the ink discharge module 80. The ink supply module 90 may be connected to the ink discharge module 80 through one or more flow paths. In an embodiment, for example, the ink supply module 90 may be supported by the supporter 10. In addition, for example, the ink supply module 90 may be secured to at least one of the first moving portion 40, the second moving portion 50, the third moving portion 60, and the connection frame 70. However, this is an example and the arrangement of the ink supply module 90 is not limited thereto. For another example, the ink supply module 90 may be arranged outside the supporter 10 to supply ink to the ink discharge module 80.

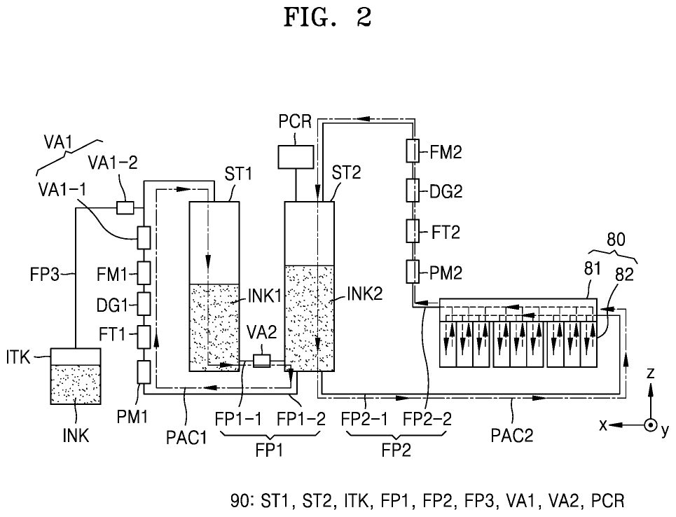

FIG. 2 to FIG. 5 are schematic cross-sectional views of an ink supply module and an ink discharge module according to an embodiment.

Referring to FIG. 2 to FIG. 5, it may be seen that the ink supply module 90 supplies ink INK to the ink discharge module 80.

The ink supply module 90 may include, a first storage unit ST1, a second storage unit ST2, an ink tank ITK, a first flow path FP1, a second flow path FP2, a third flow path FP3, a first valve VA1, a second valve VA2, a first pump PM1, a second pump PM2, a first degasser DG1, a second degasser DG2, a first filter FT1, a second filter FT2, first flowmeter FM1, second flowmeter FM2, and a pressure regulator PCR.

The first storage unit ST1 and the second storage unit ST2 may store ink INK. The first storage unit ST1 and the second storage unit ST2 may be connected to each other. The second storage unit ST2 may be connected to the ink discharge module 80. Hereinafter, the ink INK stored in the first storage unit ST1 will be referred to as the first storage ink INK1, and the ink INK stored in the second storage unit ST2 will be referred to as the second storage ink INK2.

The ink tank ITK may store the ink INK. The ink tank ITK may be connected to the first storage unit ST1. The ink tank ITK may supply ink INK to the first storage unit ST1. In an embodiment, for example, the ink tank ITK may have a separate pump, and the ink INK in storage may be supplied to the first storage unit ST1 through the pump.

The first flow path FP1 may connect the first storage unit ST1 and the second storage unit ST2 to each other such that a first ink circulation path PAC1 is formed in which the ink INK circulates between the first storage unit ST1 and the second storage unit ST2. Ink INK may circulate between the first storage unit ST1 and the second storage unit ST2 through the first flow path FP1.

The first flow path FP1 may include a 1-1 flow path FP1-1 and a 1-2 flow path FP1-2. The 1-1 flow path FP1-1 may be a flow path through which the first storage ink INK1 flows to the second storage unit ST2. The 1-2 flow path FP1-2 may be a flow path through which the second storage ink INK2 flows to the first storage unit ST1. In other words, the ink INK may flow from the first storage unit ST1, sequentially through the 1-1 flow path FP1-1, the second storage unit ST2, and the 1-2 flow path FP1-2, and back to the first storage unit ST1.

The second flow path FP2 may connect the second storage unit ST2 and the ink discharge module 80 to each other such that a second ink circulation path PAC2 is formed in which ink INK circulates between the second storage unit ST2 and the ink discharge module 80. The ink INK may circulate between the second storage unit ST2 and the ink discharge module 80 through the second flow path FP2.

The second flow path FP2 may include a 2-1 flow path FP2-1 and a 2-2 flow path FP2-2. The 2-1 flow path FP2-1 may be a flow path through which the second storage ink INK2 flows to the ink discharge module 80. The 2-2 flow path FP2-2 may be a flow path through which the ink INK that has passed through the ink discharge module 80 flows to the second storage unit ST2. In other words, the ink INK may flow from the second storage unit ST2, sequentially through the 2-1 flow path FP2-1, the ink discharge module 80, and the 2-2 flow path FP2-2, and back to the second storage unit ST2.

The third flow path FP3 may form an ink supply path PAS in which ink INK is supplied from the ink tank ITK to the first storage unit ST1. The ink INK may flow from the ink tank ITK to the first storage unit ST1 through the third flow path FP3. The third flow path FP3 may be connected to the first flow path FP1. In an embodiment, for example, the third flow path FP3 may be connected to the 1-2 flow path FP1-2. Therefore, ink INK may flow from the ink tank ITK to the first storage unit ST1 through the third flow path FP3 and the 1-2 flow path FP1-2 sequentially.

The first valve VA1 may control the flow of ink INK at a contact point of the first flow path FP1 and the third flow path FP3. The first valve VA1 may be arranged adjacent to the contact point of the first flow path FP1 and the third flow path FP3. When the first valve VA1 is open, the ink INK may pass through the first valve VA1, and when the first valve VA1 is closed, the ink INK cannot pass through the first valve VA1.

The first valve VA1 may include a 1-1 valve VA1-1 and a 1-2 valve VA1-2. The 1-1 valve VA1-1 may be arranged on the first flow path FP1. The 1-2 valve VA1-2 may be arranged on the third flow path FP3. The 1-1st valve VA1-1 may be arranged on the 1-2 flow path FP1-2 before the ink INK passes through the contact point of the first flow path FP1 and the third flow path FP3. The 1-1 valve VA1-1 may control the flow of the ink INK passing through the 1-2 flow path FP1-2, and the 1-2 valve VA1-2 may control the flow of the ink INK passing through the third flow path FP3.

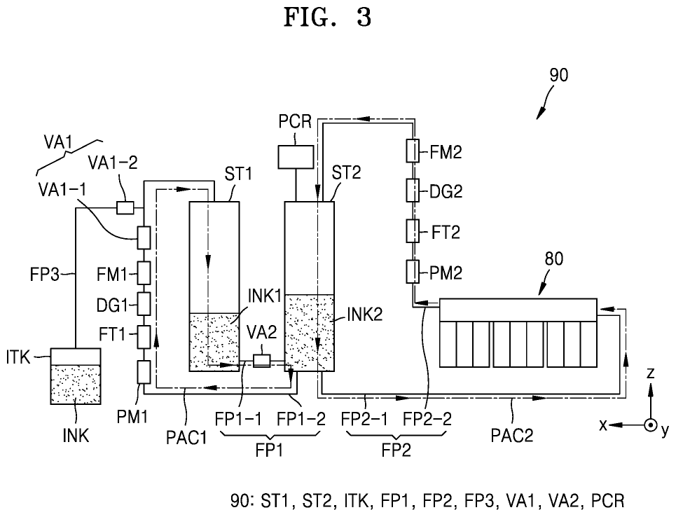

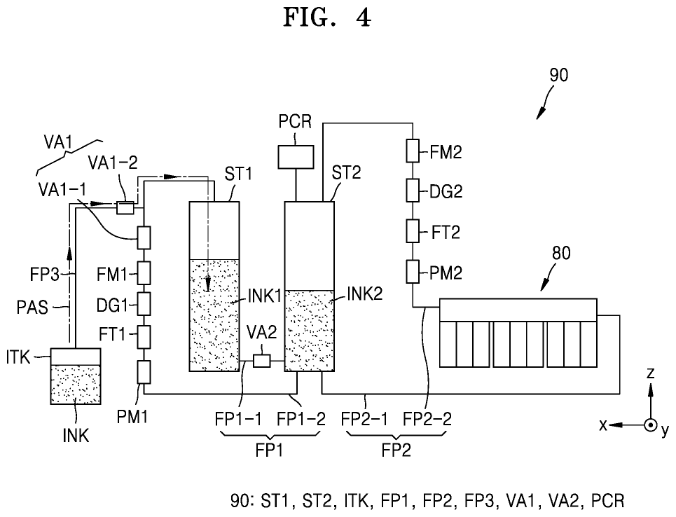

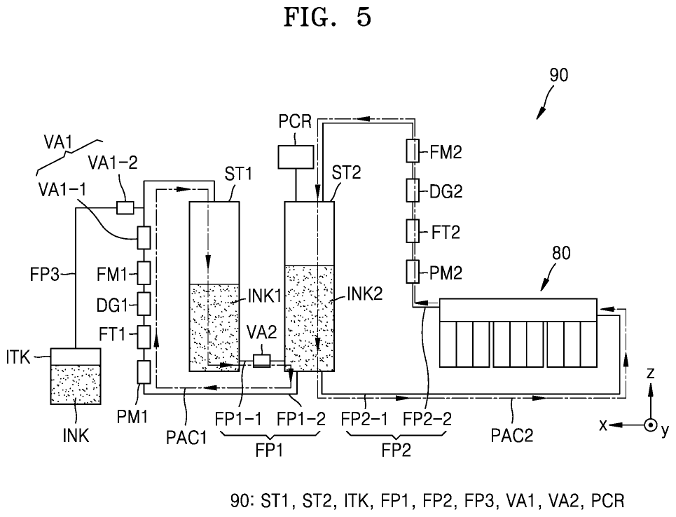

The 1-1 valve VA1-1 and the 1-2 valve VA1-2 may operate in opposition to each other. In an embodiment, for example, as shown in FIG. 2, FIG. 3, and FIG. 5, when the 1-1 valve VA1-1 is opened, the 1-2 valve VA1-2 may be closed. Accordingly, the ink supply path PAS may be deactivated and the first ink circulation path PAC1 may be activated. In addition, as shown in FIG. 4, when the 1-1 valve VA1-1 is closed, the 1-2 valve VA1-2 may be opened. Accordingly, the ink supply path PAS may be activated and the first ink circulation path PAC1 may be deactivated.

The second valve VA2 may be arranged on the 1-1 flow path FP1-1. The second valve VA2 may control the flow of ink INK passing through the 1-1 flow path FP1-1. When the second valve VA2 is open, the ink INK may pass through the second valve VA2, and when the first valve VA1 is closed, the ink INK cannot pass through the second valve VA2. Therefore, when the second valve VA2 is open, the ink INK may pass through the 1-1 flow path FP1-1, and when the second valve VA2 is closed, the ink INK cannot pass through the 1-1 flow path FP1-1.

The first pump PM1 may be arranged on the first flow path FP1. In an embodiment, for example, the first pump PM1 may be arranged on the 1-2 flow path FP1-2. The first pump PM1 may provide power so that the ink INK circulates along the first ink circulation path PAC1.

The second pump PM2 may be arranged on the second flow path FP2. In an embodiment, for example, the second pump PM2 may be arranged on the 2-2 flow path FP2-2. The second pump PM2 may provide power so that the ink INK circulates along the second ink circulation path PAC2.

The first degasser DG1 may be arranged on the first flow path FP1. Therefore, the first degasser DG1 may remove air bubbles that form in the ink INK passing through the first flow path FP1. In an embodiment, for example, the first degasser DG1 may be arranged on the 1-2 flow path FP1-2. Therefore, the first degasser DG1 may remove air bubbles formed in the ink INK passing through the 1-2 flow path FP1-2.

The second degasser DG2 may be arranged on the second flow path FP2. Therefore, the second degasser DG2 may remove air bubbles formed in the ink INK passing through the second flow path FP2. In an embodiment, for example, the second degasser DG2 may be arranged on the 2-2 flow path FP2-2. Therefore, the second degasser DG2 may remove air bubbles formed in the ink INK passing through the 2-2 flow path FP2-2.

The first filter FT1 may be arranged on the first flow path FP1. Therefore, the first filter FT1 may filter the ink INK passing through the first flow path FP1. In an embodiment, for example, the first filter FT1 may filter impurities passing through the first flow path FP1 along with the ink INK. Alternatively, the first filter FT1 may filter a coagulated portion of the ink INK passing through the first flow path FP1. In an embodiment, for example, the first filter FT1 may be arranged on the 1-2 flow path FP1-2.

The second filter FT2 may be arranged on the second flow path FP2. Therefore, the second filter FT2 may filter the ink INK passing through the second flow path FP2. In an embodiment, for example, the second filter FT2 may filter impurities passing through the second flow path FP2 along with the ink INK. Alternatively, the second filter FT2 may filter a coagulated portion of the ink INK passing through the second flow path FP2. In an embodiment, for example, the second filter FT2 may be arranged on the 2-2 flow path FP2-2.

A first flowmeter FM1 may be arranged on the first flow path FP1. The first flowmeter FM1 may detect a flow rate of the ink INK flowing through the first flow path FP1. The first pump PM1 may be operated based on information detected by the first flowmeter FM1. The first pump PM1 may operate such that the flow rate of the ink INK detected by the first flowmeter FM1 falls within a specified range. In an embodiment, for example, the first flowmeter FM1 may be arranged on the 1-2 flow path FP1-2.

A second flowmeter FM2 may be arranged on the second flow path FP2. The second flowmeter FM2 may detect a flow rate of ink INK flowing through the second flow path FP2. The second pump PM2 may operate based on information detected by the second flowmeter FM2. The second pump PM2 may operate such that the flow rate of the ink INK detected by the second flowmeter FM2 falls within a specified range. In an embodiment, for example, the second flowmeter FM2 may be arranged on the 2-2 flow path FP2-2.

The pressure regulator PCR may adjust pressure in the second storage unit ST2. The pressure regulator PCR may adjust the pressure inside the second storage unit ST2 such that the pressure inside the second storage unit ST2 is lower than pressure inside the first storage unit ST1. In an embodiment, for example, the pressure inside the first storage unit ST1 may be atmospheric pressure, and the pressure inside the second storage unit ST2 may be negative pressure.

The ink discharge module 80 may include a distributor 81 and a sprayer 82.

The distributor 81 may be connected to the second flow path FP2. One side of the distributor 81 may be connected to the 2-1 flow path FP2-1 and the other side of the distributor 81 may be connected to the 2-2 flow path FP2-2. The ink INK may flow into the distributor 81 through the 2-1 flow path FP2-1, and may flow out of the distributor 81 through the 2-2 flow path FP2-2. The distributor 81 may distribute ink INK to the sprayer 82.

The sprayer 82 is connected to the distributor 81 and may spray the ink INK. The sprayer 82 may be provided in plurality and may be arranged in a row along one direction (for example, the x-axis direction). Each of the plurality of sprayers 82 may be supplied with ink INK from the distributor 81. The plurality of sprayers 82 may spray the ink INK, and the un-sprayed ink INK may be supplied back to the distributor 81. In other words, in the process of spraying the ink INK, the ink INK may flow between the distributor 81 and the sprayers 82.

The ink discharge module 80 may be provided with a separate valve. Depending on the degree to which the valve is opened or closed, the amount of ink INK sprayed from the sprayers 82 may be adjusted. Since a negative pressure is formed inside the second storage unit ST2, a negative pressure may also be applied to the 2-2 flow path FP2-2. Therefore, the phenomenon of the ink INK flowing out of the sprayer 82 by gravity may be reduced. Accordingly, the amount of ink INK sprayed from the sprayer 82 may be easily adjusted.

First, referring to FIG. 2, a first state of the ink supply module 90 may be seen. The first state refers to a state in which the first ink circulation path PAC1 is formed. In the first state, the ink supply path PAS is deactivated, and the first ink circulation path PAC1 may be activated. In other words, in the first state, the 1-1 valve VA1-1 and the second valve VA2 may be open and the 1-2 valve VA1-2 may be closed. In this process, the ink INK may be circulated by flowing sequentially through the first storage unit ST1, the 1-1 flow path FP1-1, the second storage unit ST2, the 1-2 flow path FP1-2, and the first storage unit ST1. Therefore, the phenomenon of the ink INK solidifying or settling by gravity over time may be reduced.

In addition, in the first state, a second ink circulation path PAC2 may be formed. In this process, the ink INK may circulate while flowing sequentially through the second storage unit ST2, the 2-1 flow path FP2-1, the ink discharge module 80, the 2-2 flow path FP2-2, and the second storage unit ST2. As the ink INK passes through the ink discharge module 80, the ink discharge module 80 may discharge the ink INK.

With the second valve VA2 in an open state, the pressure inside the second storage unit ST2 is lower than the pressure inside the first storage unit ST1, and thus the level of the second storage ink INK2 may be higher than the level of the first storage ink INK1.

Referring to FIG. 3, it may be seen that the first state of the ink supply module 90 continues. As the ink discharge module 80 continuously discharges the ink INK, the first storage ink INK1 and the second storage ink INK2 may be consumed. Therefore, the level of the first storage ink INK1 and the second storage ink INK2 may decrease. The second storage unit ST2 may be provided with a level sensor (not shown) that detects the level of the second storage ink INK2. When the level of the second storage ink INK2 detected by the level sensor (not shown) provided in the second storage unit ST2 falls below a specified value, the first state may be converted to the second state. The second state will be described below with reference to FIG. 4.

Referring to FIG. 4, the second state of the ink supply module 90 may be seen. The ink supply module 90 may be convertible between the first state and the second state. The second state refers to a state in which an ink supply path PAS is formed. In the second state, the ink supply path PAS is activated, and the first ink circulation path PAC1 may be deactivated. That is, in the second state, the 1-2 valve VA1-2 may be open and the 1-1 valve VA1-1 may be closed. In the second state, the ink tank ITK may supply a specified amount of ink INK to the first storage unit ST1. In this process, the ink INK may be supplied from the ink tank ITK to the first storage unit ST1 through the third flow path FP3 and the 1-2 flow path FP1-2.

In the second state, the second valve VA2 may be closed. Therefore, the level of the ink INK stored in the first storage unit ST1 increases, but the level of the ink INK stored in the second storage unit ST2 may be constant. In addition, in the second state, the second ink circulation path PAC2 (see FIG. 3) may be deactivated. Therefore, in the second state, the ink discharge module 80 may not discharge ink INK. In an embodiment, for example, the second ink circulation path PAC2 may be deactivated by closure of a separate valve provided inside the ink discharge module 80.

Therefore, since the level of the ink INK stored in the second storage unit ST2 is constant in the second state, the phenomenon in which the quality of the ink discharge module 80 decreases due to a sudden change in the level of the ink INK stored in the second storage unit ST2 may be reduced. Here, the quality of the ink discharge module 80 may refer to the uniformity of the amount of ink INK discharged by the ink discharge module 80. That is, the ink discharge module 80 may discharge ink INK uniformly in a first state and may not discharge ink INK in a second state.

When the ink tank ITK completes supplying a specified amount of ink INK to the first storage unit ST1, the ink supply module 90 may convert from the second state back to the first state. The process will be described below with reference to FIG. 5.

Referring to FIG. 5, the process of conversion of the ink supply module 90 from the second state to the first state may be seen.

When converting from the second state to the first state, the first ink circulation path PAC1 may be formed by opening the 1-1 valve VA1-1 and the second valve VA2 and closing the 1-2 valve VA1-2. As the second valve VA2 is opened, the first storage ink INK1 may flow to the second storage unit ST2. Accordingly, the level of the first storage ink INK1 may be lowered and the level of the second storage ink INK2 may be raised. When the level of the second storage ink INK2 no longer changes, the second ink circulation path PAC2 may be activated. In an embodiment, for example, the second ink circulation path PAC2 may be activated by opening a separate valve provided inside the ink discharge module 80.

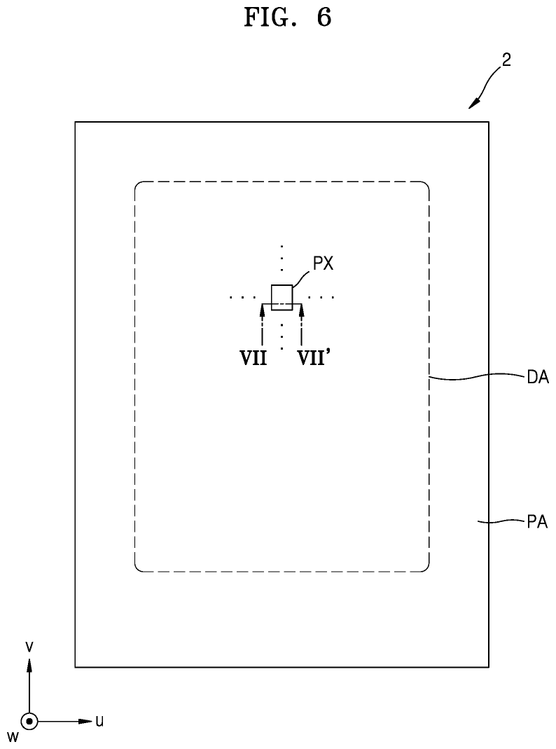

FIG. 6 is a top view schematically illustrating a display device according to an embodiment.

Referring to FIG. 6, a display device 2 manufactured according to an embodiment may include a display area DA and a peripheral area PA located on an outer side of the display area DA. The display device 2 may provide an image by an array of a plurality of pixels PX arranged two-dimensionally in the display area DA.

The peripheral area PA is an area that does not provide an image, and may completely or partially surround the display area DA. The peripheral area PA may include drivers or the like for providing electrical signals or power to the pixel circuits corresponding to each of the pixels PX. The peripheral area PA may include pads, which are areas to which electronic devices, printed circuit boards, etc. may be electrically connected.

Hereinafter, the display device 2 will be described as including an organic light-emitting diode OLED as a light-emitting element, but the display device 2 of the disclosure is not limited thereto. In another embodiment, the display device 2 may be a light-emitting display device including inorganic light-emitting diodes, in other words, may be an inorganic light-emitting display. The inorganic light-emitting diodes may include PN diodes including an inorganic semiconductor-based material. When a voltage is applied to the PN junction diode in the forward direction, holes and electrons are injected, and the energy generated by the recombination of the holes and electrons is converted into light energy to emit light of a certain color. The inorganic light-emitting diodes described above may have a width of about 1 to about 1000 micrometers, and in some embodiments, the inorganic light-emitting diodes may be referred to as micro-LEDs. As another embodiment, the display device 2 may be a quantum dot light-emitting display.

The display device 2 may be utilized as a display screen for a variety of products, including portable electronic devices such as mobile phones, smart phones, tablet personal computers, mobile communication terminals, electronic notebooks, e-books, portable multimedia players (“PMPs”), navigation devices, and ultra-mobile PCs (“UMPCs”), etc., as well as televisions, laptops, monitors, billboards, internet of things (“IOT”) devices, etc. In addition, the display device 2 according to an embodiment may be utilized in a wearable device, such as a smart watch, a watch phone, an eyewear-type display, and a head-mounted display (“HMD”). In addition, the display device 2 according to an embodiment may be used in an instrument panel of an automobile, and as a center information display (“CID”) arranged on the center fascia or dashboard of an automobile, as a room mirror display in place of a side mirror of an automobile, as entertainment for the back seat of an automobile, and as a display screen arranged on the back of a front seat.

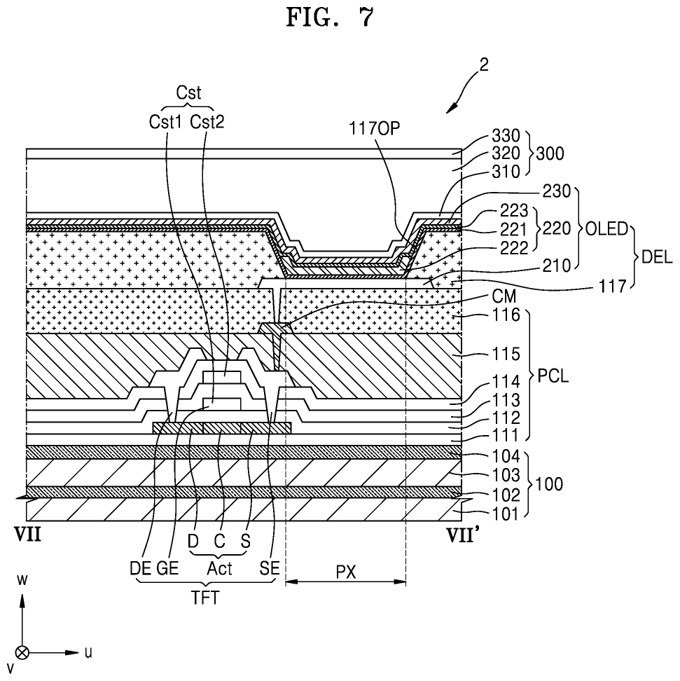

FIG. 7 is a cross-sectional view schematically illustrating a display device according to an embodiment, which may correspond to a cross-section of the display device taken along line VII-VII′ in FIG. 6.

Referring to FIG. 7, the display device 2 may include a stacked structure of a substrate 100, a pixel circuit layer PCL, a display element layer DEL, and an encapsulation layer 300.

The substrate 100 may be a multi-layer structure including a base layer, which includes a polymeric resin, and an inorganic layer. In an embodiment, for example, the substrate 100 may include a base layer, which includes a polymeric resin, and a barrier layer of an inorganic insulation layer. In an embodiment, for example, the substrate 100 may include a first base layer 101, a first barrier layer 102, a second base layer 103, and a second barrier layer 104, which are stacked sequentially. The first base layer 101 and the second base layer 103 may include polyimide (“PI”), polyethersulfone (“PES”), polyarylate, polyetherimide (“PEI”), polyethyelenene napthalate (“PEN”), polyethylene terephthalate (“PET”), polyphenylene sulfide (“PPS”), polycarbonate, cellulose triacetate (“TAC”), and/or cellulose acetate propionate (“CAP”), or the like. The first barrier layer 102 and the second barrier layer 104 may include an inorganic insulation material such as silicon oxide, silicon oxynitride, and/or silicon nitride. The substrate 100 may have flexible properties.

A pixel circuit layer PCL is disposed on the substrate 100. FIG. 7 illustrates that the pixel circuit layer PCL includes a thin-film transistor TFT, a buffer layer 111, a first gate insulation layer 112, a second gate insulation layer 113, an interlayer insulation layer 114, a first planarized insulation layer 115, and a second planarized insulation layer 116, disposed below and/or above components of the thin-film transistor TFT.

The buffer layer 111 may reduce or block the infiltration of debris, moisture, or foreign air from a lower portion of the substrate 100, and may provide a flat surface on the substrate 100. The buffer layer 111 may include an inorganic insulation material such as silicon oxide, silicon oxynitride, or silicon nitride, and may be a single-layer or multi-layer structure including any of the aforementioned materials.

The thin-film transistor TFT on the buffer layer 111 includes a semiconductor layer Act, and the semiconductor layer Act may include poly-silicon (poly-Si). Alternatively, the semiconductor layer Act may include amorphous silicon (a-Si), may include an oxide semiconductor, and may include an organic semiconductor or the like. The semiconductor layer Act may include a channel area C and, arranged on each side of the channel area C, a drain area D and a source area S. A gate electrode GE may overlap the channel area C in a plan view.

The gate electrode GE may include a low-resistance metal material. The gate electrode GE may include a conductive material including molybdenum (Mo), aluminum (Al), copper (Cu), titanium (Ti), etc., and may be formed as a multi-layer or a single layer including the above materials.

The first gate insulation layer 112 between the semiconductor layer Act and the gate electrode GE may include an inorganic insulation material such as silicon oxide (SiO₂), silicon nitride (SiNₓ), silicon oxide (SiON), aluminum oxide (Al₂O₃), titanium oxide (TiO₂), tantalum oxide (Ta₂O₅), hafnium oxide (HfO₂), or zinc oxide (ZnOₓ) or the like. The zinc oxide (ZnOₓ) may be zinc oxide (ZnO) and/or zinc peroxide (ZnO₂).

The second gate insulation layer 113 may be provided to cover the gate electrode GE. The second gate insulation layer 113 may include an inorganic insulation material such as silicon oxide (SiO₂), silicon nitride (SiNₓ), silicon oxide (SiON), aluminum oxide (Al₂O₃), titanium oxide (TiO₂), tantalum oxide (Ta₂O₅), hafnium oxide (HfO₂), or zinc oxide (ZnOₓ) or the like, similar to the first gate insulation layer 112. The zinc oxide (ZnOₓ) may be zinc oxide (ZnO) and/or zinc peroxide (ZnO₂).

On top of the second gate insulation layer 113, an upper electrode Cst2 of the storage capacitor Cst may be disposed. The upper electrode Cst2 may overlap the gate electrode GE below the upper electrode Cst2 in a plan view. In this case, the gate electrode GE and the upper electrode Cst2, which overlap the second gate insulation layer 113 located therebetween, may form a storage capacitor Cst. That is, the gate electrode GE may function as a lower electrode Cst1 of the storage capacitor Cst.

As such, the storage capacitor Cst and the thin-film transistor TFT may be formed to overlap each other in a plan view. In some embodiments, the storage capacitor Cst may be formed to not overlap the thin-film transistor TFT in a plan view.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multi-layer of the aforementioned materials.

The interlayer insulation layer 114 may cover the upper electrode Cst2. The interlayer insulation layer 114 may include silicon oxide (SiO₂), silicon nitride (SiNₓ), silicon oxide (SiON), aluminum oxide (Al₂O₃), titanium oxide (TiO₂), tantalum oxide (Ta₂O₅), hafnium oxide (HfO₂), zinc oxide (ZnOₓ), or the like. The zinc oxide (ZnOₓ) may be zinc oxide (ZnO) and/or zinc peroxide (ZnO₂). The interlayer insulation layer 114 may be a single layer or a multi-layer, including the inorganic insulation material described above.

The drain electrode DE and the source electrode SE may each be located on the interlayer insulation layer 114. The drain electrode DE and the source electrode SE may be connected to the drain area D and the source area S, respectively, through contact holes formed in insulation layers beneath the drain electrode DE and the source electrode SE. The drain electrode DE and the source electrode SE may include a material with good conductivity. The drain electrode DE and the source electrode SE may include a conductive material including molybdenum (Mo), aluminum (Al), copper (Cu), titanium (Ti), etc., and may be formed as a multi-layer or a single layer, including the above materials. In an embodiment, the drain electrode DE and the source electrode SE may have a multi-layer structure of Ti/Al/Ti.

The first planarized insulation layer 115 may cover the drain electrode DE and the source electrode SE. The first planarized insulation layer 115 may include organic insulation materials such as general-purpose polymers such as polymethylmethacrylate (“PMMA”) or polystyrene (“PS”), polymer derivatives that have a phenolic group, acrylic-based polymers, imide-based polymers, aryl ether-based polymers, amide-based polymers, fluorinated polymers, p-xylene-based polymers, vinyl alcohol-based polymers, and blends thereof.

The second planarized insulation layer 116 may be disposed on the first planarized insulation layer 115. The second planarized insulation layer 116 may include the same materials as the first planarized insulation layer 115, and may include organic insulation materials such as general-purpose polymers such as polymethylmethacrylate (PMMA) or polystyrene (PS), polymer derivatives that have a phenolic group, acrylic-based polymers, imide-based polymers, aryl ether-based polymers, amide-based polymers, fluorinated polymers, p-xylene-based polymers, vinyl alcohol-based polymers, and blends thereof.

A display element layer DEL may be arranged on the pixel circuit layer PCL having the structure described above. The display element layer DEL may include an organic light-emitting diode OLED as a display element (in other words, a light-emitting element), and the organic light-emitting diode OLED may include a stacked structure of a pixel electrode 210, an intermediate layer 220, and a common electrode 230. The organic light-emitting diode OLED, for example, may emit red, green, or blue light or may emit red, green, blue, or white light. The organic light-emitting diode OLED emits light through a light-emitting area, and the light-emitting area may be defined as a pixel PX.

The pixel electrode 210 of the organic light-emitting diode OLED may be electrically connected to the thin-film transistor TFT through contact holes formed in the second planarized insulation layer 116 and the first planarized insulation layer 115 and a contact metal CM disposed on the first planarized insulation layer 115.

The pixel electrode 210 may include a conductive oxide such as indium tin oxide (“ITO”), indium zinc oxide (“IZO”), zinc oxide (ZnO), indium oxide (In₂O₃), indium gallium oxide (IGO), or aluminum zinc oxide (AZO). In another embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or compounds thereof. In another embodiment, the pixel electrode 210 may further include a film formed of ITO, IZO, ZnO, or In₂O₃, above/below the reflective film described above.

Disposed on the pixel electrode 210 is a bank layer 117 that defines an opening 117OP exposing a central portion of the pixel electrode 210. The bank layer 117 may include an organic insulation material and/or an inorganic insulation material. The opening 117OP may define a light-emitting area for light emitted by the organic light-emitting diode OLED. In an embodiment, for example, the size/width of the opening 117OP may correspond to the size/width of the light-emitting area. Therefore, the size and/or width of the pixel PX may depend on the size and/or width of the opening 117OP of the corresponding bank layer 117.

The intermediate layer 220 may include an emission layer 222 formed to correspond to the pixel electrode 210. The emission layer 222 may include a polymeric or low-molecular-weight organic material that emits a certain color of light. Alternatively, the emission layer 222 may include an inorganic light-emitting material, or may include quantum dots.

In an embodiment, the intermediate layer 220 may include a first functional layer 221 and a second functional layer 223, arranged below and above the emission layer 222, respectively. The first functional layer 221 may include, for example, a hole transport layer (“HTL”), or may include a hole transport layer and a hole injection layer (“HIL”). The second functional layer 223 is a component disposed above the emission layer 222 and may include an electron transport layer (“ETL”) and/or an electron injection layer (“EIL”). The first functional layer 221 and/or the second functional layer 223 may be a common layer formed to cover the entire substrate 100, as is the common electrode 230, which will be described below.

The common electrode 230 is disposed on the pixel electrode 210 and may overlap the pixel electrode 210 in a plan view. The common electrode 230 may be made of a low-work-function conductive material. In an embodiment, for example, the common electrode 230 may include a (semi-) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), an alloy thereof, or the like. Alternatively, the common electrode 230 may further include a layer such as ITO, IZO, ZnO, or In₂O₃ on the (semi-) transparent layer including the materials described above. The common electrode 230 may be integrally formed to cover the entire substrate 100.

The encapsulation layer 300 may be disposed on the display element layer DEL and cover the display element layer DEL. The encapsulation layer 300 includes at least one inorganic encapsulation layer and at least one organic encapsulation layer, and as an example, FIG. 7 illustrates that the encapsulation layer 300 includes a first inorganic encapsulation layer 310, an organic encapsulation layer 320, and a second inorganic encapsulation layer 330, which are stacked sequentially.

The first inorganic encapsulation layer 310 and the second inorganic encapsulation layer 330 may include one or more inorganic materials selected from aluminum oxide, titanium oxide, tantalum oxide, hafnium oxide, zinc oxide, silicon oxide, silicon nitride, and silicon oxynitride. The organic encapsulation layer 320 may include a material of the polymer family. Polymer-based materials may include acrylic-based resins, epoxy-based resins, polyimides, polyethylene, etc. In an embodiment, the organic encapsulation layer 320 may include acrylate. The organic encapsulation layer 320 may be formed by curing a monomer, or by applying a polymer. The organic encapsulation layer 320 may be transparent.

Although not shown, a touch sensor layer may be arranged on the encapsulation layer 300, and an optical functional layer may be arranged on the touch sensor layer. The touch sensor layer may obtain coordinate information according to an external input, for example, a touch event. The optical functional layer may reduce reflectance of light (external light) incident toward the display device from the outside and/or improve color purity of light emitted from the display device. In an embodiment, the optical functional layer may include a retarder and/or a polarizer. The retarder may be a film type or a liquid crystal coating type, and may include a λ/2 retarder and/or a λ/4 retarder. The polarizer may also be a film type or a liquid crystal coating type. The film type may include a stretchable synthetic resin film, and the liquid crystal coating type may include liquid crystals arranged in a certain arrangement. The retarder and the polarizer may further include a protective film.

An adhesive member may be arranged between the touch electrode layer and the optical functional layer. As the adhesive member, general adhesive members known in the art may be employed without limitation. The adhesive member may be a pressure-sensitive adhesive (“PSA”).

At least one of the pixel circuit layer PCL, the display element layer DEL, and the encapsulation layer 300 may include ink discharged from the ink discharge module 80 described with reference to FIG. 1 to FIG. 5.

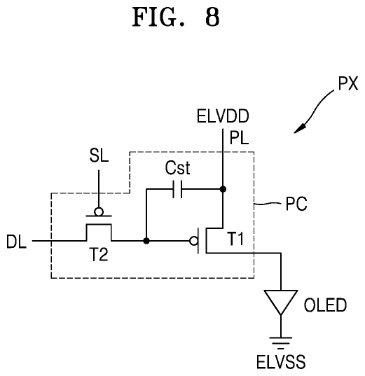

FIG. 8 is an equivalent schematic view of any pixel of a display panel according to an embodiment.

Each pixel PX may include a pixel circuit PC, and a display element connected to the pixel circuit PC, such as an organic light-emitting diode OLED. The pixel circuit PC may include a first thin-film transistor T1, a second thin-film transistor T2, and a storage capacitor Cst. Each pixel PX may emit light, such as red, green, blue or white light, via an organic light-emitting diode OLED.

The second thin-film transistor T2 is a switching thin-film transistor, connected to a scan line SL and a data line DL, and data voltage input from the data line DL may be transferred to the first thin-film transistor T1, based on a switching voltage input from the scan line SL. The storage capacitor Cst is connected to the second thin-film transistor T2 and a driving voltage line PL, and may store a voltage corresponding to the difference between a voltage received from the second thin-film transistor T2 and a first power supply voltage ELVDD supplied to the driving voltage line PL.

The first thin-film transistor T1 is a driving thin-film transistor, which is connected to the driving voltage line PL and the storage capacitor Cst, and may control a drive current flowing from the driving voltage line PL to the organic light-emitting diode OLED in response to a voltage value stored in the storage capacitor Cst. The organic light-emitting diode OLED may emit light that has a certain luminance due to the drive current. A counter electrode (for example, cathode) of the organic light-emitting diode OLED may be supplied with a second power supply voltage ELVSS.

FIG. 8 illustrates a pixel circuit PC including two thin-film transistors and one storage capacitor, but the present disclosure is not limited thereto. The number of thin-film transistors and the number of storage capacitors may be variously changed according to the design of the pixel circuit PC. In an embodiment, for example, the pixel circuit PC may further include four, five or more thin-film transistors in addition to the two thin-film transistors described above.

The disclosure has thus been described with reference to embodiments shown in the drawings, which are only for example, and those skilled in the art will understand that various modifications and variations of the embodiments are possible therefrom. Therefore, the true technical scope of protection of the disclosure should be determined by the technical idea of the appended claims.

Embodiments may improve the manufacturing quality of display devices by enabling the ink discharge module to discharge ink uniformly.

The effects of the disclosure are not limited to the effects mentioned above, and other effects not mentioned will be clearly understood by those skilled in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display device, comprising:
a stage on which a display substrate is mounted;
an ink discharge module configured to discharge ink onto the display substrate; and
an ink supply module configured to supply the ink to the ink discharge module,
wherein the ink supply module comprises:
a first storage unit configured to store ink;
a second storage unit configured to store the ink, and connected to the first storage unit and the ink discharge module;
an ink tank configured to store the ink and to supply the ink to the first storage unit;
a first flow path connecting the first storage unit and the second storage unit to each other, such that a first ink circulation path is formed in which the ink circulates between the first storage unit and the second storage unit;
a second flow path connecting the second storage unit and the ink discharge module to each other, such that a second ink circulation path is formed in which the ink circulates between the second storage unit and the ink discharge module; and
a third flow path forming an ink supply path in which the ink is supplied from the ink tank to the first storage unit,
wherein the ink supply module is convertible between a first state in which the first ink circulation path is formed, and a second state in which the ink supply path is formed.

2. The apparatus of claim 1,
wherein the ink supply module further comprises a first valve configured to control a flow of the ink at a contact point of the first flow path and the third flow path.

3. The apparatus of claim 2,
wherein the first valve comprises:
a 1-1 valve arranged on the first flow path; and
a 1-2 valve arranged on the third flow path,
wherein in the first state, the 1-1 valve is open and the 1-2 valve is closed, and in the second state, the 1-1 valve is closed and the 1-2 valve is open.

4. The apparatus of claim 1,
wherein the first flow path comprises:
a 1-1 flow path through which the ink stored in the first storage unit flows into the second storage unit; and
a 1-2 flow path through which the ink stored in the second storage unit flows into the first storage unit,
wherein the ink supply module further comprises
a second valve arranged on the 1-1 flow path.

5. The apparatus of claim 4,
wherein in the first state, the second valve is open, and in the second state, the second valve is closed.

6. The apparatus of claim 1,
wherein the ink supply module further comprises a pressure regulator configured to adjust pressure inside the second storage unit.

7. The apparatus of claim 6,
wherein the pressure regulator adjusts the pressure inside the second storage unit such that the pressure inside the second storage unit is lower than pressure inside the first storage unit.

8. The apparatus of claim 7,
wherein the pressure inside the first storage unit is atmospheric pressure.

9. The apparatus of claim 1,
wherein the ink supply module is configured to convert from the first state to the second state when a level of the ink stored in the second storage unit falls below a specified value.

10. The apparatus of claim 1,
wherein the ink discharge module comprises:
a distributor connected to the second flow path and configured to distribute the ink to a plurality of sprayers; and
the plurality of sprayers connected to the distributor and configured to spray the ink.

11. A method of manufacturing a display device, comprising:
placing a display substrate on a stage;
discharging ink onto the display substrate by an ink discharge module; and
supplying the ink to the ink discharge module,
wherein the supplying of the ink to the ink discharge module comprises:
a first circulation process in which the ink circulates through a first storage unit and a second storage unit through a first flow path;
a second circulation process in which the ink circulates through the second storage unit and the ink discharge module through a second flow path; and
a supply process in which the ink flows from an ink tank to the first storage unit through a third flow path.

12. The method of claim 11,
wherein the supplying of the ink to the ink discharge module further comprises controlling a flow of the ink at a contact point of the first flow path and the third flow path by a first valve.

13. The method of claim 12,
wherein the first valve comprises:
a 1-1 valve arranged on the first flow path; and
a 1-2 valve arranged on the third flow path;
wherein, in the first circulation process, the first valve is open and the first valve is closed, and
in the supply process, the 1-1 valve is closed and the 1-2 valve is open.

14. The method of claim 11,
wherein the first flow path comprises:
a 1-1 flow path through which the ink stored in the first storage unit flows into the second storage unit; and
a 1-2 flow path through which the ink stored in the second storage unit flows into the first storage unit,
wherein a second valve is arranged on the 1-1 flow path.

15. The method of claim 14,
wherein in the first circulation process, the second valve is open, and in the supply process, the second valve is closed.

16. The method of claim 11,
wherein the supplying of the ink to the ink discharge module further comprises a pressure adjusting process in which pressure inside the second storage unit is adjusted.

17. The method of claim 16,
wherein the pressure adjusting process comprises
adjusting the pressure in the second storage unit such that the pressure inside the second storage unit is lower than pressure inside the first storage unit.

18. The method of claim 17,
wherein the pressure inside the first storage unit is atmospheric pressure.

19. The method of claim 11,
wherein the supply process begins when the ink stored in the second storage unit falls below a specified level.

20. The method of claim 11,
wherein the ink discharge module comprises:
a distributor connected to the second flow path and configured to distribute the ink to a plurality of sprayers; and
the plurality of sprayers connected to the distributor and configured to spray the ink.
